(19) United States
(12) Patent Application Publication
(10) Pub. No.: US 2008/0150056 A1
(43) Pub. Date: Jun. 26, 2008

(54) METHOD FOR MANUFACTURING IMAGE SENSOR

(75) Inventor: Sang Sik KIM, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/949,199

(22) Filed: Dec. 3, 2007

(30) Foreign Application Priority Data
Dec. 21, 2006 (KR) 10-2006-0132231

(51) Int. Cl. H01L 31/0232; H01L 31/18

(52) U.S. Cl. 257/432; 438/65; 257/E31.127

(57) ABSTRACT

A method is provided for manufacturing an image sensor. In the method, a plurality of wires and dielectric films are formed on a substrate including a photodiode. A color filter is formed on the dielectric film. A micro lens is formed on the color filter. A protection film is coated at a preset thickness on the micro lens and the color filter. A back grinding process is performed and a back of the substrate is grinded. A sawing process is performed and the image sensor is packaged.

### CROSS-REFERENCE TO RELATED APPLICATION

This application claims priority to Korean Application No. 10-2006-0132231, filed on Dec. 21, 2006, which is incorporated herein by reference in its entirety.

### BACKGROUND

### FIELD OF THE INVENTION

The present invention relates to a method for manufacturing an image sensor, and more particularly, to a method for manufacturing an image sensor in which damage to a lens and a color filter of the image sensor is prevented when back grinding a substrate where the image sensor is formed.

### BACKGROUND OF THE INVENTION

In general, a Complementary Metal Oxide Semiconductor (CMOS) image sensor includes a photodiode for generating an electrical signal in response to an amount of received light and a logic circuit part for converting an electrical signal generated from the photodiode into data.

In an image sensor for realizing a color image, a color filter is formed to be at a distance from an upper side of a photodiode. The color filter may have color elements including three colors, such as red, green, and blue. Alternatively, the color filter can have color elements that include the colors of yellow, magenta, and cyan.

Light passing through the color filter passes through a plurality of dielectric films between the color filter and the photodiode before reaching the photodiode. Therefore, there inevitably occurs a loss of light to some extent because of refractive indexes and transmittances of the dielectric films.

FIG. 1 is a diagram illustrating an image sensor in accordance with the conventional art.

In FIG. 1, a field insulating film 102 may be formed in a field region of a semiconductor substrate 101, such as single crystalline silicon, for electrical insulation between unit pixels of the image sensor. A photodiode 103, which is a light receiving element, may be formed in an active region of the semiconductor substrate 101.

A first wire 104 may be formed of polycrystalline silicon on the field insulating film 102. A first dielectric film 105 may be formed and planarized on the resultant structure including the first wire 104. A second wire 106 may be formed of aluminum on the first dielectric film 105. A second dielectric film 107 may be formed and planarized on the resultant structure including the second wire 106.

A third wire 108, being of aluminum, for example, and a third dielectric film 109 may be formed over the second dielectric film 107. A light block layer 110 may be formed of aluminum on the third dielectric film 109.

A central opening may be provided at a center of the light block layer 110, the opening having a circular shape or a rectangular shape. The light block layer 110 serves to block incident light from outside of a region for the photodiode 103 while the central opening allows incident light within the region for the photodiode 103 to pass.

A fourth dielectric film 111 is formed and planarized on the third dielectric film 109 and the light block layer 110. The fourth dielectric film 111 may protect a device from external moisture and scratches. The fourth dielectric film 111 can be comprise a single layer such as an oxide film or a nitride film. Alternately, the fourth dielectric film 111 can include a laminate film comprised of an oxide film and a nitride film.

A color filter 112 may be formed of color substance on the fourth dielectric film 111. Over Coating Material (OVM) 113 may formed of photosensitive material on the color filter 112 to control a focus distance. A micro lens 114 may be formed of a polymer material on the OVM 113.

The micro lens 114, being formed of polymer, is weak in mechanical strength. Accordingly, in the conventional art, Low Temperature Oxide (LTO) 115, for example, silane (SiH4) oxide, is laminated on the micro lens 114 using a Plasma Enhanced Chemical Vapor Deposition (PECVD) process to protect the micro lens 114.

However, effectiveness of the micro lens 114 is deteriorated because of the LTO 115 that is laminated on the micro lens 114 as a protection film.

### SUMMARY OF SOME EXAMPLE EMBODIMENTS

In general, example embodiments of the invention relate to a method for manufacturing an image sensor in which damage to a micro lens and a color filter is prevented during a back grinding process.

In accordance with one example embodiment, there is provided a method for manufacturing an image sensor. The method includes forming a plurality of wires and dielectric films on a substrate including a photodiode. Next, a color filter may be formed on the dielectric film and a micro lens may be formed on the color filter. A protection film may then be coated at a preset thickness on the micro lens and the color filter. The protection film may be a polymer elastomer. Once the protection film is coated, a back grinding process may be applied to a back of the substrate. Finally, a sawing process may be performed and the image sensor may be packaged.

In accordance with another example embodiment, there is provided a method for manufacturing an image sensor in which a micro lens is protected from damage potentially resulting from a back grinding process performed as part of a packaging process. The method may include coating polymer elastomer at a preset thickness on the micro lens, attaching a back grinding adhesive tape to the polymer elastomer, and performing a back grinding process, which may involve grinding a back of a wafer in which the image sensor is formed. Next, a sawing process may be performed on the wafer. The back grinding adhesive tape and the coated polymer elastomer may be removed after the sawing process is performed.

### BRIEF DESCRIPTION OF THE DRAWINGS

Aspects of example embodiments of the invention will become apparent from the following description of example embodiments given in conjunction with the accompanying drawings, in which:

FIG. 1 is a diagram illustrating an image sensor in accordance with the conventional art;

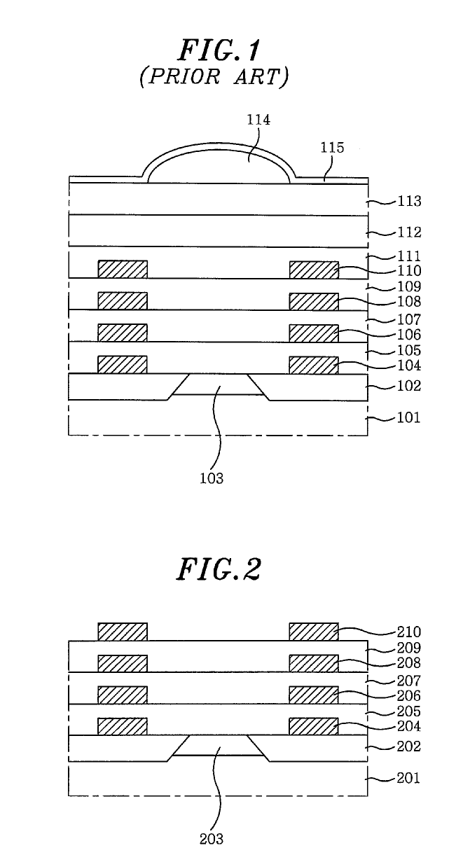

FIGS. 2 to 4 are diagrams illustrating a method for manufacturing an image sensor in accordance with an exemplary embodiment of the present invention; and

FIG. 5 is a flowchart illustrating a method for manufacturing an image sensor in accordance with the present invention.

### DETAILED DESCRIPTION OF SOME EXAMPLE EMBODIMENTS

Hereinafter, aspects of example embodiments of the present invention will be described in detail with reference to the accompanying drawings so that they can be readily implemented by those skilled in the art.

In the accompanying drawings, several layers and regions are magnified and shown in thickness for clear expression. The same or like parts are denoted by the same reference numerals throughout the specification.

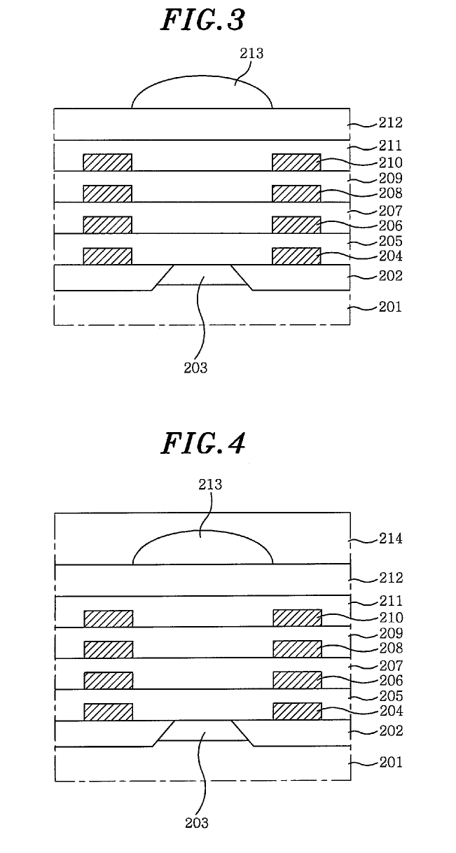

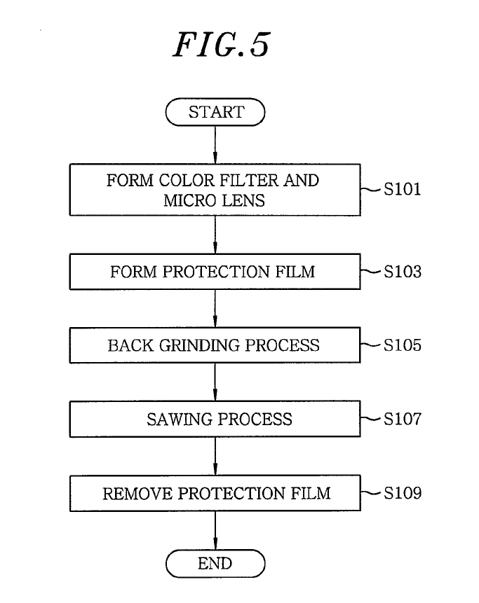

FIGS. 2 to 4 are diagrams illustrating an exemplary method for manufacturing an image sensor. FIG. 5 is a flowchart illustrating an exemplary method for manufacturing an image sensor.

Referring to FIG. 2, a field insulating film 202 such as a field oxide film may be formed to electrically insulate unit pixels of the image sensor in a field region of a substrate 201.

A unit pixel may be formed in an active region of the substrate 201. The unit pixel may include a photodiode 203 that is a light receiving element.

A multi layer wiring structure may be formed on the resultant structure.

In particular, a first wire 204 may be formed of polycrystalline silicon material on the field oxide film 202. For interlayer insulation, a first dielectric film 205 may be laminated and planarized on the first wire 204 and the photodiode 203.

A second wire 206 may be positioned at an upper side of the first wire 204. The second wire 206 may be formed of aluminum material on the first dielectric film 205. For interlayer insulation, a second dielectric film 207 may be laminated and planarized on the first dielectric film 205 and the second wire 206.

A third wire 208 may be formed of aluminum material on the second dielectric film 207 above the first wire 204. For interlayer insulation, a third dielectric film 209 may be laminated and planarized on the second dielectric film 207 and the third wire 208.

A light block layer 210 may be formed of aluminum material to have a thickness of about 4000 Å on the third dielectric film 209.

Although FIG. 2 shows a structure comprised of three layers of wires, including the first wire 204 through the third wire 208, a structure comprising four layers of wires or more can be formed depending on the particular characteristics of a device.

Referring to FIG. 3, a fourth dielectric film 211 may be formed on the third dielectric film 209 and the light block layer 210. The fourth dielectric film 211 may be formed to protect the device from external moisture or scratch. The fourth dielectric film 211 can be formed using a single layer such as an oxide film or a nitride film or can be formed using a laminate film comprised of an oxide film and a nitride film.

After formation of the fourth dielectric film 211, a pattern of a color filter 212 may be formed on the fourth dielectric film 211 using a photolithography process. For purposes of illustration, FIG. 3 shows only one color filter 212 per pixel, but multiple color filters corresponding to multiple colors per pixel may actually be formed.

A micro lens 213 may be formed on the color filter 212.

Referring to FIG. 4, a protection film 214 may be formed on the micro lens 213 to protect the micro lens 213.

The protection film 214 may be formed to fully cover the micro lens 213 and the color filter 212. This is to prevent damage of the micro lens 213 and the color filter 212 during a back grinding work to be described later.

The protection film 214 may be formed by coating polymer elastomer, such as PolyDiMethylSiloxane (PDMS), at a thickness of about 5 μm to 100 μm. After the back grinding process is performed, the protection film 214 may be removed.

The PDMS material, being an elastomer, has a different expansion coefficient than the micro lens 213. Thus, the PDMS material is advantageous in that it does not react with the underlying micro lens because of a difference of surface tension and separation is easy.

A method for manufacturing an image sensor in accordance with an exemplary embodiment will be described with reference to FIG. 5. A plurality of wires and dielectric films may be formed over a substrate including a light receiving photodiode and then, a color filter may be formed on the dielectric films. A micro lens is formed on the color filter (Step 101).

Prior to a back grinding process and a sawing process for packaging the image sensor, PDMS may be coated as a protection film, with a preset thickness, on the micro lens and the color filter (Step 103).

After a back grinding adhesive tape may be attached to the PDMS, the back grinding process may be performed to grind a back of a wafer (Step 105). The back grinding process for grinding the back of the wafer may be performed to reduce a size of the image sensor before the packaging of the image sensor.

After that, the sawing process may be performed to saw the wafer for packaging (Step 107).

Next, the back grinding adhesive tape may be removed. After that, the coated protection film of PDMS may be removed from the micro lens and the color filter (Step 109), thereby completing a procedure of manufacturing the image sensor.

In addition to damage from contamination or scratching by external particles, the micro lens and the color filter may be damaged by a back grinding adhesive tape for grinding a back of a wafer. Therefore, before the back grinding adhesive tape is attached to the micro lens 203 and the color filter 212 in preparation for a back grinding process, a protection film 214 may be coated on the micro lens 203 and the color filter 212.

Thus, the protection film 214 may be coated on the micro lens 213 and the color filter 212 to prevent the micro lens 213 and the color filter 212 from being damaged due to the back grinding adhesive tape used.

The protection film 214 may be formed by coating polymer elastomer, such as PDMS, at a thickness of about 5 μm to 100 μm. The protection film 214 may serve as a buffer layer for preventing big foreign particles that may be stuck to a surface of the back grinding adhesive tape from sticking to the micro lens 213 or the color filter 212.

A sawing process may be performed to saw a wafer substrate in which the micro lens 213 and the color filter 212 are formed. After the sawing process, the protection film 214 is removed.

In a method for manufacturing an image sensor, there is an advantage of preventing damage of a micro lens and a color filter in a back grinding process.

While the invention has been shown and described with respect to the preferred embodiments, it will be understood by those skilled in the art that various changes and modifications may be made without departing from the spirit and scope of the invention as defined in the following claims.

What is claimed is:

1. A method for manufacturing an image sensor, the method comprising:
forming a plurality of wires and dielectric films on a substrate comprising a photodiode;
forming a color filter on the dielectric film;
forming a micro lens on the color filter;
coating a protection film at a preset thickness on the micro lens and the color filter;
performing a back grinding process to grind a back of the substrate; and
performing a sawing process to package the image sensor,
wherein the protection film is polymer elastomer.

2. The method of claim 1, wherein the polymer elastomer is PolyDiMethylSiloxane (PDMS).

3. The method of claim 1, further comprising: removing the protection film after the sawing process is performed.

4. The method of claim 1, wherein the polymer elastomer is coated at a thickness of 5 μm to 100 μm.

5. A method for manufacturing an image sensor in a process of packaging the image sensor to protect a micro lens from a back grinding process, the method comprising:
coating polymer elastomer at a preset thickness on the micro lens;
attaching a back grinding adhesive tape to the polymer elastomer;
performing a back grinding process to grind a back of a wafer in which the image sensor is formed;
performing a sawing process to saw the wafer; and
removing the back grinding adhesive tape and the coated polymer elastomer.

6. The method of claim 5, wherein the wherein the polymer elastomer is PolyDiMethylSiloxane (PDMS).

7. The method of claim 5, wherein the polymer elastomer is coated at a thickness of 5 μm to 100 μm.

8. An image sensor comprising:
a plurality of wires and dielectric films formed on a substrate comprising a photodiode;
a color filter formed on the dielectric film;
a micro lens formed on the color filter;
a protection film coated at a preset thickness on the micro lens and the color filter.
